(19) United States
(12) Patent Application Publication
(10) Pub. No.: US 2026/0111621 A1
(43) Pub. Date: Apr. 23, 2026

(54) Non-uniform perforated inverse conical flow spreader in intermittent blowdown wind tunnel

(71) Applicant: VIETTEL GROUP, Ha Noi City (VN)

(72) Inventors: TRUONG GIANG NGUYEN, Hanoi (VN); QUOC HUY NGHIEM, Hanoi (VN); BA MINH PHAM, Hanoi (VN); TIEN QUYET NGUYEN, Hanoi (VN); PHI MINH NGUYEN, Hanoi (VN)

(73) Assignee: VIETTEL GROUP, Ha Noi City (VN)

(21) Appl. No.: 19/336,132

(22) Filed: Sep. 22, 2025

(30) Foreign Application Priority Data
Oct. 17, 2024 (VN) 1-2024-07806

(51) Int. Cl. G06F 30/17; G01M 9/04

(52) U.S. Cl. CPC G06F 30/17; G01M 9/04

(57) ABSTRACT

The aerodynamic design method of the non-uniform perforated inverse conical flow spreader (PICFS) used in intermittent blowdown wind tunnel. This device, which is installed inside the wind tunnel's plenum chamber, is to slow down and to spread uniformly flow coming from the inlet pipe by means of tearing apart it into numerous small jets and letting those jets coalesce. This invention discovers that at least for square inlet pipe shape, a non-uniformly perforated device offers superior downstream flow uniformity to that of a uniformly perforated one. Therefore, the design process has been proposed to obtain improved freestream velocity distortion at the plane locating about 1.0-1.5 times of plenum chamber's diameter D downstream of the flow spreader, where typically is installed aerodynamic device such as honeycomb flow straightener or turbulence screen.

### TECHNICAL FIELD

This invention relates to the aerodynamic design method of the non-uniform perforated inverse conical flow spreader (PICFS) (FIG. 1). This PICFS, in form of either uniform perforation or non-uniform perforation, is typically used in intermittent blow down high speed wind tunnel, i.e., Mach 0.6 above.

A PICFS typically is constructed from a formed and then welded thin steel plate, on which there are number of perforations for aerodynamics purpose.

The flow spreader (2) (FIG. 1) is installed inside the plenum chamber system (FIG. 2). It follows an inlet pipe (1) by the distance dump gap (d). It has diameter being equal to the plenum chamber's diameter (D) (3). Downstream of the plenum chamber, there is a throat (4) to accelerate flow to desired speed.

In many cases, an inlet pipe has circular cross sectional shape. However, this does not cover all design problems. This invention focuses on the case where an inlet pipe having square cross sectional shape, such as an inlet pipe downstream of a square turning section with welded turning guide vanes.

For application, this non-uniform flow spreader offers not only for blow-down wind tunnels but also for other aero-related test rig that needs a flow decelerating device and a plenum chamber such as pressure loss test rig for the heat exchanger in commercial aircraft or gas turbine compressor and combustor test rig.

### TECHNICAL STATUS OF THE INVENTION

The function of a perforated inverse conical flow spreader (PICFS), as its name suggests, is to expand the incoming flow into a wide angle and short distance path. The flow is now forced downstream through a number of small holes perforated in the PICFS's wall. By going through these holes, the flow is essentially torn into a number of small jets corresponded. These jets coalesce themselves to form a relatively stable and slow speed flow, i.e., without large scale flow fluctuation, which may harm a wind tunnel structure.

Without a PICFS, a slowing flow must undergo inverse pressure gradient process which contain long narrow angle diffuser channel(s) yet still susceptible to upstream flow's fluctuation source such as flow control valve's movement.

The biggest advantage of PICFS over other flow decelerating device is its stability over upstream flow's fluctuation by self-damping characteristics of these jet's coalescence.

This design method focuses on the case of installation PICFS downstream of a square cross sectional inlet as it demands unconventional perforation technique. FIG. 2 illustrates this design concept.

Generally, a PICFS has been widely incorporated successfully in many ground-based testing facilities such as Air Force Aero Propulsion Laboratory [1], Aerospace Research Laboratory [2], Florida Center for Advanced Aero-Propulsion [3]. However, details disclosed are insufficient to re-create similar function design.

Two important academic books firstly proposing a PICFS are the one by Gollin et al. [4] and the one by Ferri et al. [5]. Still, only brief introduction of general working principles of this device exists. The recommendation that jets velocity through perforation should be less than Mach 0.5 seems satisfied at room temperature by default. There is no overall design guideline mentioning all the following parameters that designer must consider during design process:
Dump gap
Porosity (openness ratio)
Number of holes perforated
Perforation uniformity in radial direction

In short, it has not been recorded any published papers discussing design process that calls the four variables above at the same time.

For practical design and fabrication purpose, it is proposed a design process for the non-uniform perforated inverse conical flow spreader used in wind tunnel's plenum chamber for decelerating flow. This design features reliable aerodynamic quality as well as fabrication convenience.

### TECHNICAL PRINCIPLE OF THE INVENTION

As pointed out firstly in the books of Gollin et al. [4] and Ferri et al. [5], the PICFS mechanism is utilized for the following three purposes:
Decelerating stably a high speed incoming flow to low speed in a plenum chamber, i.e. no macro flow fluctuation in both upstream and downstream of a PICFS regardless of incoming condition such as shock pressure due to upstream control valve's movement.
Decelerating uniformly that flow to certain level that enables installation of aerodynamic devices such as honeycomb and turbulence screen inside a plenum chamber, downstream of a PICFS. The experience-based criteria is such that freestream velocity distortion should be and could be adjusted to be less than, for example, 150% where freestream velocity distortion is defined as follows [6]:

$${Distortion}_{level} = \frac{{V}_{max} - {V}_{min}}{{V}_{avg}} * 100$$

Total pressure drop across a PICFS should be 1.0 qₑ where qₑ is dynamic pressure in a inlet pipe. Too high pressure drop would cause a decrease in wind tunnel's running duration.
   These above goals are achieved via controlling 4 design parameters:
Dump gap, which is defined as the distance from an incoming pipe's exit plane to a PICFS's apex. Dump gap is chosen to be the shortest length possible to distribute flow to PICFS's conical surface.
Porosity, which determines average jet velocities across perforated holes on a PICFS. Porosity is chosen to offer sufficient low these jet velocities to be well below Mach 0.5 while balancing PICFS's mechanical strength
Number of perforations, which largely affects level of pressure drop as well as level of flow stability across a PICFS. Higher number of perforations produce higher level of aerodynamic stability but also costs higher loss. Mechanical fabrication tooling size is also taken into account for convenience.
Perforation uniformity determines level of flow's uniform distribution downstream of a PICFS. Unfortunately, uniform perforation on PICFS does not always result in high level of flow uniformity. Due to inverse shape of a PICFS, those holes near its center often ask for more ample size to compensate quick loss of dynamic pressure. Non-uniform PICFS performance has been published in [7].

### BRIEF DESCRIPTION OF THE DRAWINGS

FIG. 1 describes the general shape of a non-uniform PICFS where near-center perforation is larger than those in rear region;

FIG. 2 shows the usage of a non-uniform PICFS where it is installed inside a plenum chamber;

FIG. 3 describes the design flow chart to form a non-uniform PICFS;

FIG. 4 shows an example CFD result of flow field downstream of a uniform PICFS where high velocity region is spilled out of center region; and

FIG. 5 shows an example CFD result of flow field downstream of a non-uniform PICFS, where flow field is more uniform than that of a uniform PICFS;

### DETAILED DESCRIPTION OF THE INVENTION

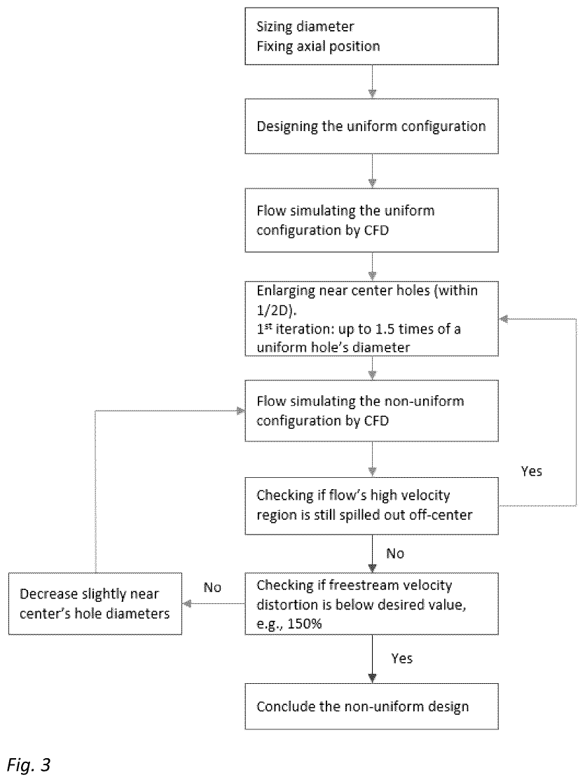

The following paragraphs describe clearly and exhaustively the design process of a non-uniform perforated inverse conical flow spreader (PICFS) (FIG. 3). This description is just examples not mentioning all possible outcomes of the invention. It will be apparent to those skilled in the art that many changes and modifications may be made without departing from the broader aspects. The appended claims are therefore intended to cover all such changes and modifications as fall within the true spirit and scope of the technology.

Due to typically ample size of perforations and typically non-compressible flow characteristics inside a plenum chamber, it is decided that commercial Computational Fluid Dynamics (CFD) software tools such as ANSYS Fluent offers high fidelity result in PICFS performance analysis. Thus, ANSYS Fluent is used as a simulation and assessment tool to compare various results.
(1) The first step is to fix a PICFS in axial position. There is a term called “dump gap” d being the distance from an incoming pipe's exit plane to a PICFS's apex. The higher dump gap value, the more likely that incoming flow has chance to spread over a PICFS's conical surface. But this will cost of higher system's overall length. Based on practical experience, the satisfied dump gap d is chosen between one-third to one-half of an incoming pipe's hydraulic diameter.
(2) The second step is to build a uniform configuration, which is the base for further modification. Since the overall shape of a PICFS is fixed by its overall diameter being equal to plenum chamber's diameter and the conical angle being equal to 90°, there are 02 parameters left are porosity and number of perforations.

Porosity (openness ratio) is chosen by balancing between jet velocities through perforation's requirement and PICFS's mechanical strength. Porosity here is defined based on projection of perforations axially on cross sectional area of a plenum chamber. High porosity reduces jet velocities, which is asked to be well below Mach 0.5. Also, high porosity depletes PICFS's mechanical strength. Based on experience, porosity value around 40%±2% is chosen because plenum chamber's velocity often less than 80 ft/s.

Number of perforations, on another hand, contributes largely on flow stability and level of pressure drop across a PICFS. The higher number of perforations, the higher level of flow stability but the higher cost of pressure loss. Bearing in mind that the total pressure drop across a PICFS should be in order of 1.0 qₑ where qₑ is the dynamic pressure upstream of a PIFCS, the number of perforations is recommended between 900-1000 ones. Level of 40%±2% porosity and number of perforations determine the size of average perforation. Since perforation is often fabricated by drilling method, the number of perforations is chosen for convenient tool size.

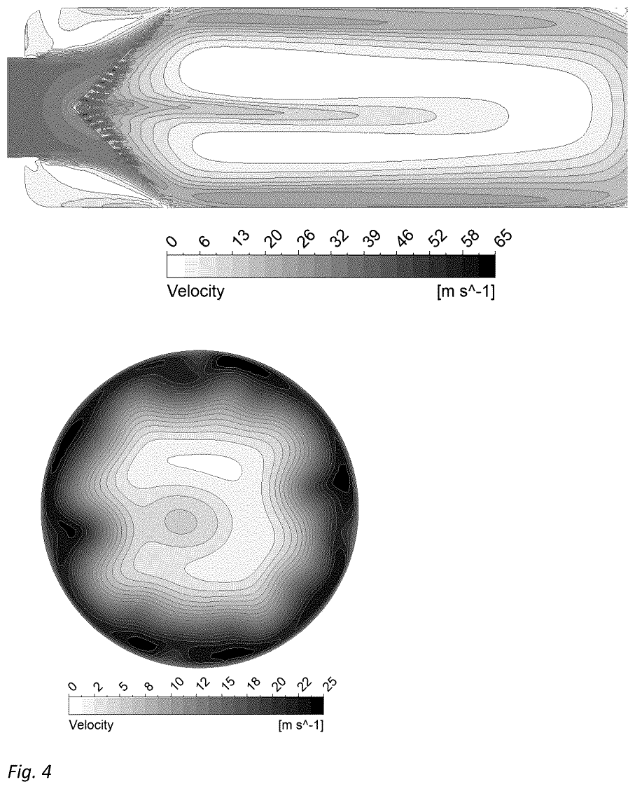

Note that these holes are randomly distributed over a conical surface to obtain stabilized flow, i.e., to prevent harmonized symptom.
(3) An interim uniform PICFS is undergone CFD analysis for performance feedback. One can easily detect that high velocity stream is pushed off-center. Flow is very stable, but the center space is occupied by low-velocity stream. An example case is presented on the FIG. 4. This is less desirable because it causes high freestream velocity distortion. High velocity distortion again limit working efficiency of aerodynamic devices such as honeycomb flow straightener and turbulence screen.

This flow behavior could be explained as jets emanating from near center holes undergo longer distances than that of jet in rear area. They quickly got coalesced and get lost their dynamic pressure. Loss of dynamic pressure raises static pressure. And high static pressure, in turn, pushes other jets away in radial direction. Thus, high velocity region is off-center.
(4) The reason above suggests that center perforations should be enlarged to give their corresponding jets more energy for deeper travelling distance. Those center perforations should be within one-half of plenum chamber diameter D and based on experience, they should be enlarged up to near 1.5 times of the original uniform hole size, tooling size convenience should be paid attention also. Noted that the overall porosity of 40%±2% should be maintained, so that the number of perforations decrease. By doing so, total pressure loss across a PICFS is also reduced.
(5) A then—1^{st} iteration non-uniform PICFS is then undergone CFD simulation to analyze its properties. If high velocity flow is still spilled out off-center, then center perforation should be enlarged further to give corresponding jets more energy, especially those within one-fourth of chamber's diameter D.
(6) If high velocity flow is no longer pushed away radially, then freestream velocity distortion at a target plane is checked to be within desired criterion or not. Typically, this target plane is from 1.0 D to 1.5 D downstream of a PICFS, depending on specific application and aerodynamic devices installed. If freestream velocity distortion is higher than desired value, center perforations are larger than necessary size. So, their size should be decreased. This starts a new design fine-tuning loop until satisfied result appeared.

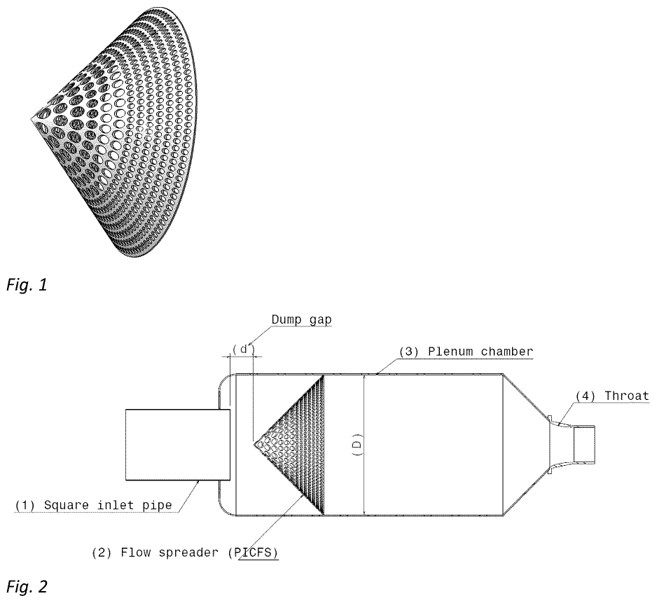

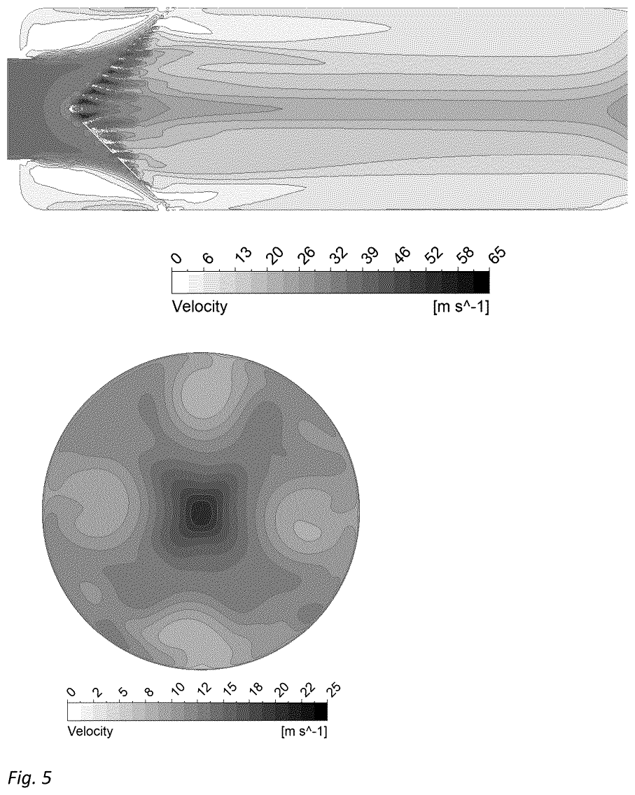

For example, on the FIG. 5, freestream velocity distortion is less than 150% at 2D downstream of a PICFS for installation of honeycomb flow straightener. On the target cross sectional plane, it offers superior result than that of uniform PICFS on FIG. 4. Velocity distribution are more uniform. Peak velocity is lower than that on FIG. 4 while bottom velocity is higher; thus improving significantly freestream velocity distortion.
(7) The concluded non-uniform PICFS design should be converged to look like the one on FIG. 1.

### REFERENCES

[1] Wennerstrom, A. J., Derose, R. D., Law, C. W. and Buzzell, W. A., 1976. Investigation of a 1500 ft./sec. Transonic, High-Through-Flow, Single-Stage Axial-Flow Compressor with Low Hub/Tip Ratio. Aerospace Research Laboratories, Wright-Patterson Air Force Base, AD B. 16506.
[2] Fiore, A. W., Moore, D. G., Murray, D. H. and West, J. E., 1975. Design and calibration of the ARL Mach 3 high Reynolds number facility (p. 0184). Aerospace Research Laboratories.
[3] Arora, N., Ali, M. Y. and Alvi, F. S., 2016. Flowfield of a 3-D swept shock boundary layer interaction in a Mach 2 flow. In 46th AIAA fluid dynamics conference (p. 3649).
[4] Pope, A. and Goin, K., High-speed wind tunnel testing, 1965.
[5] Ferri, A. and Bogdonoff, S. M., 1954. Design and operation of intermittent supersonic wind tunnels: AGAR Dograph AG-1. NATO Advisory Group for Aeronautic Research and Development.
[6] Lominac, J. K. and Boytos, J. F., 1998, June. Aeropropulsion environmental test facility. In Turbo Expo: Power for Land, Sea, and Air (Vol. 78637, p. V002T02A015). American Society of Mechanical Engineers.
[7] Nguyen, T. G., Nghiem, Q. H., Nguyen, Q. H., Nguyen, N. V., Chu, D. L. and Nguyen, P. M., DEVELOPMENT OF THE LOW-COST AND LIMITED SPACE SEA-LEVEL RAM AIR TEST (RAT) MACH 0.8 SYSTEM.

1. A non-uniform perforated inverse conical flow spreader (PICFS) and its design process in which:
A design loop is imitated by setting the following parameters, building an initial uniform PICFS:
(Step 1) Dump gap d is to be within one-third to one-half of an incoming pipe's hydraulic diameter
(Step 2) Porosity is to be within 40%±2% and number of perforations is around 900-1000 holes, a number chosen depends on convenient drilling tool size available;
(Step 3) An initial uniform PICFS is then undergone flow examination to decide that at step 4, center perforations, i.e. those within ½ D chamber diameter, must be enlarged while maintaining porosity, enlargement, which is up to 1.5 times of the original hole size in step 2, is to compensate kinetic energy loss of jets emanating from those holes, this technique results in non-uniform PICFS shape but more uniform flow distribution than that created by a uniform PICFS;
(Step 5) If high velocity flow region is still spilled off-center, center perforations need further enlargement;
(Step 6) When high velocity is no longer spilled off-center, flow uniformity is assessed by freestream velocity distortion formula criterion being less than 150% at a target plane to decide if center perforations require narrowing down or not, a target plane is typically 1.0 D to 1.5 D chamber diameter downstream of a PICFS, where aerodynamic devices like honeycomb flow straightener or turbulence screen are installed.
